(19) United States
(12) Patent Application Publication
(10) Pub. No.: US 2024/0162279 A1
(43) Pub. Date: May 16, 2024

(54) METHOD OF FABRICATING A CAPACITOR

(71) Applicant: STMicroelectronics International N.V., Geneva (CH)

(72) Inventors: Vincent CARO, Chambray Les Tours (FR); Quentin Paoli, Tours (FR)

(21) Appl. No.: 18/385,036

(22) Filed: Oct. 30, 2023

(30) Foreign Application Priority Data
Nov. 14, 2022 (FR) 2211799

(51) Int. Cl. H01G 4/30; H01J 37/32; H01L 21/02; H01L 21/311; H01L 21/3213

(52) U.S. Cl. CPC H01L 28/75; H01J 37/32816; H01L 21/02068; H01L 21/31116; H01L 21/31144; H01L 21/32136; H01L 21/32139

(57) ABSTRACT

The present disclosure relates to a method of fabricating a capacitor, comprising the following successive steps of: a) forming a stack including, in order from the top face of a first conductive layer, a first electrode, a dielectric layer, a second electrode, and a second conductive layer; b) forming by photolithography, a masking layer on a face of the second conductive layer opposite to the second electrode; c) etching by a chlorinated physicochemical plasma etching, through said masking layer, a top part of the stack, said chlorinated physicochemical plasma etching being stopped within the dielectric layer; d) etching by a fluorinated physicochemical plasma etching, through said masking layer, a bottom part of the stack, said fluorinated physicochemical plasma etching being stopped on the top face of the first conductive layer; and e) removing the masking layer.

### CROSS REFERENCE TO RELATED APPLICATION

This application claims the priority benefit of French Patent Application Number 22/11799, filed on Nov. 14, 2022, entitled “Procedédé fabrication d'un condensateur,” which is hereby incorporate by reference in its entirety.

### TECHNICAL FIELD

The present disclosure generally relates to the fabrication of an integrated circuit and more particularly targets the fabrication of an integrated circuit including a capacitor, for example a passive integrated circuit, for example a RC filter (including a resistor, and a capacitor), a LC filter (including an inductor, and a capacitor), or a RLC filter (including a resistor, an inductor, and a capacitor).

### BACKGROUND

Numerous methods of fabricating integrated circuits including capacitors have been provided. These methods have various disadvantages. There is thus a need for improving the methods of fabricating an integrated circuit including a capacitor in order to overcome all or some of the drawbacks of the known methods.

### BRIEF SUMMARY

One embodiment provides a method of fabricating a capacitor, comprising the following successive steps:
a) forming a stack including, in order from the top face of a first conductive layer, a first electrode, a dielectric layer, a second electrode, and a second conductive layer;
b) forming by photolithography, a masking layer on a face of the second conductive layer opposite to the second electrode;
c) etching by a chlorinated physicochemical plasma etching, through said masking layer, a top part of the stack, said chlorinated physicochemical plasma etching being stopped within the dielectric layer;
d) etching by a fluorinated physicochemical plasma etching, through said masking layer, a bottom part of the stack, said fluorinated physicochemical plasma etching being stopped on the top face of the first conductive layer; and
e) removing the masking layer by a stripping method, and then cleaning the etched sides by a cleaning method.

According to an embodiment, the first conductive layer is an aluminium-based layer.

According to an embodiment, the second conductive layer is an aluminium-based layer.

According to an embodiment, in step c), chlorine and boron trichloride are injected in the plasma source.

According to an embodiment, in step c), the chlorine is injected at a rate comprised between 50 sccm and 120 sccm, for example in the order of 80 sccm, and the boron trichloride is injected at a rate comprised between 20 sccm and 100 sccm, for example in the order of 50 sccm.

According to an embodiment, in step c), the plasma pressure is comprised between 1.33 Pa and 6.67 Pa, for example in the order of 2 Pa, the source power is comprised between 150 W and 800 W, for example in the order of 400 W, and the biasing power is comprised between 50 W and 500 W, for example comprised between 150 W and 300 W.

According to an embodiment, in step d), sulfur hexafluoride and argon are injected in the plasma source.

According to an embodiment, in step d), the sulfur hexafluoride is injected at a rate comprised between 20 sccm and 80 sccm, for example in the order of 50 sccm, and argon is injected at a rate comprised between 10 sccm and 100 sccm, for example in the order of 20 sccm.

According to an embodiment, in step c), the plasma pressure is comprised between 0.67 Pa and 6.67 Pa, for example in the order of 1.33 Pa, the source power is comprised between 150 W and 800 W, for example in the order of 500 W, and the biasing power is comprised between 20 W and 500 W, for example in the order of 50 W.

According to an embodiment, in step e), the cleaning method comprises the cleaning of the top face and of the sides of the second conductive layer, of the sides of the second electrode, of the dielectric layer, of the first electrode, and of the top face of the first conductive layer.

According to an embodiment, the step of stripping is performed by a plasma physicochemical etching.

According to an embodiment, in the step of stripping, dioxygen and water vapour are injected in the plasma source.

According to an embodiment, in the step of stripping, the dioxygen is injected at a rate comprised between 700 sccm and 1000 sccm, for example in the order of 810 sccm, and the water vapour is injected at a rate comprised between 50 sccm and 700 sccm, for example in the order of 90 sccm or in the order of 630 sccm.

According to an embodiment, in the step of stripping, the plasma pressure is comprised between 80 Pa and 133.32 Pa, for example comprised between 100 Pa and 120 Pa and the RF power is comprised between 800 W and 1500 W, for example in the order of 1100 W.

According to an embodiment, the step of cleaning is performed using a solvent based on 2-(2-aminoethoxy)ethanol and on hydroxylamine.

According to an embodiment, the content of 2-(2-aminoethoxy)ethanol in the solvent is comprised between 55% and 65% and the content of hydroxylamine is comprised between 10% and 20%, wherein each % is % weight.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial and schematic cross-sectional view of an example capacitor; and

FIG. 2, FIG. 3, FIG. 4, and FIG. 5 illustrate successive steps of an example method of fabricating a capacitor according to another embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, we herein mainly consider the fabrication of a portion of an integrated circuit forming the capacitor. More particularly, we herein mainly consider an etching step allowing a metal layer to be uncovered in order to make an electrical contact over a bottom electrode of a capacitor of the integrated circuit. The other steps of the method of fabricating the capacitor and the integrated circuit are within the capabilities of those skilled in the art and will not be described hereafter.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

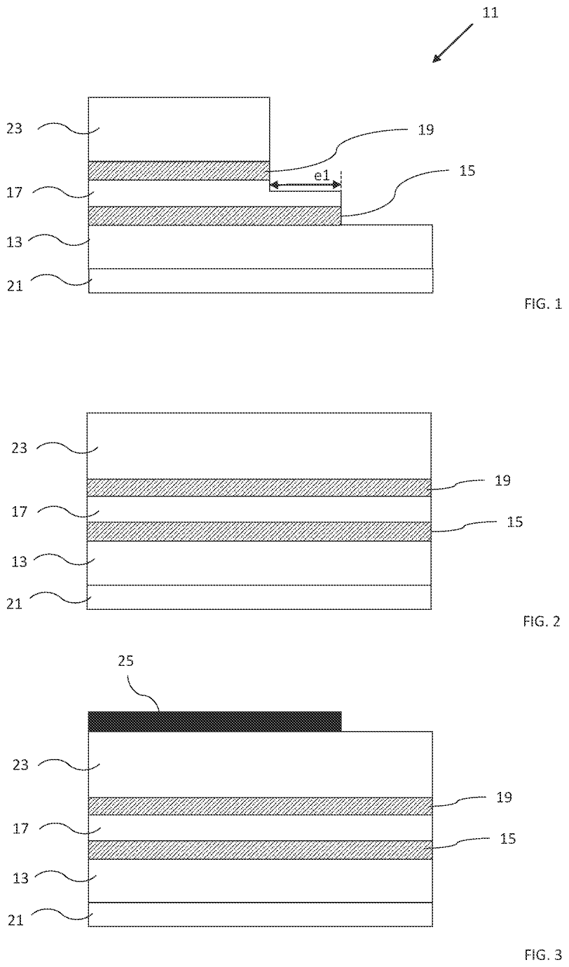

FIG. 1 is a partial and schematic cross-sectional view of an example capacitor 11.

The capacitor 11 comprises, in order from the top face of a substrate or holder 21:
a first electrically conductive layer 13, also called redistribution layer (RDL);
a first electrode 15 also called bottom electrode;
a layer 17 made of a dielectric material; a second electrode 19, also called top electrode; and a second electrically conductive layer 23.

As an example, the bottom electrode 15 contacts by its bottom face, the top face of the layer 13. The dielectric layer 17 for example contacts by its bottom face, the top face of the bottom electrode 15. The top electrode 19 for example contacts by its bottom face, the top face of the dielectric layer 17. The conductive layer 23 for example contacts by its bottom face, the top face of the top electrode 19.

As an example, the conductive layer 13 is made of a metal material. The conductive layer 13 is for example made of aluminium, or of an alloy including aluminium. The conductive layer 13 is for example made of an alloy of aluminium and copper (AlCu) or of an alloy of aluminium, copper, and silicon (AlSiCu). As an example, the layer 13 has a thickness comprised between 0.5 μm and 3 μm, for example in the order of 1.5 μm.

The electrode 15 is for example made of tantalum nitride (TaN). As an example, the electrode 15 has a thickness comprised between 20 nm and 200 nm, for example in the order of 65 nm. The electrode 19 is for example made of tantalum nitride (TaN). As an example, the electrode 19 has a thickness comprised between 20 nm and 200 nm, for example in the order of 65 nm. The electrodes 15 and 19 are for example made of the same material.

The dielectric layer 17 is for example made of silicon nitride. As an example, the dielectric layer 17 has a thickness comprised between 20 nm and 600 nm, for example comprised between 100 nm and 450 nm.

The holder 21 is for example made of silicon, preferably highly resistive. The holder 21 and the layer 13 may be spaced one apart the other with a dielectric layer, not illustrated, for example an oxide layer, for example an not-doped silicon glass (USG) or any other silicon oxide. Alternatively, the bottom conductive layer 13 contacts by its bottom face, the top face of the substrate 21. The substrate 21 for example holds one or more other elements, not illustrated, such as inductors or resistors made in the vicinity of the capacitor and electrically connected to the capacitor.

As an example, the conductive layer 23 is made of a metal material. The conductive layer 23 is for example made of a metal material capable of being etched by plasma, for example by a chlorinated plasma. As an example, the conductive layer 23 is made of aluminium, or of an aluminium-based alloy. The conductive layer 23 has for example a thickness comprised between 100 nm and 1 μm, for example in the order of 350 nm. The layer 23 especially allows the electrical conductivity of the top electrode 19 it covers to be increased.

In the example FIG. 1, the conductive layer 23, the electrode 19, and the top part of the dielectric layer 17 have their sides recessed as compared to those of electrode 15, and of the bottom part of the dielectric layer 17. In other words, a portion of the bottom part of the dielectric layer 17 is not covered with the top part of the dielectric layer 17, the top electrode 19, and the conductive layer 23. Thus, in FIG. 1, there is a first stair step between the top face of the top conductive layer 23 and the top face of the dielectric layer 17. This stair step allows an horizontal distance el between on one hand, the side of layers 23 and 19 and of the top part of the layer 17 and on the other hand, the side of the bottom part of the layer 17 and of the electrode 15 to be introduced, thus reducing the shorting chances.

As an example, the conductive layer 23, the electrode 19 and a top part of the dielectric layer 17 are in FIG. 1 vertically aligned, that is their sides are aligned. Similarly, the electrode 15 and a bottom part of the dielectric layer 17 are for example, vertically aligned.

In the example FIG. 1, the electrodes 15 and 19 and the layers 23 and 17 are recessed with respect to the conductive layer 13. In other words, a portion of the top face of the conductive layer 13 is not covered by the electrodes 15 and 19 and the layers 23 and 17. Thus, in FIG. 1, there is a second stair step between the top face of the dielectric layer 17 and the top face of the bottom conductive layer 13. This allows during a manufacturing step not detailed, an electric contact on the top electrode 15 of the capacitor to be taken, via the conductive layer 13, for example through a metal wire welded to the top face of the exposed portion of the layer 13.

As an example, in order to form the structure illustrated in FIG. 1, are first successively deposited the layer 13, the electrode 15, the layer 17, the electrode 19 and the layer 23 on the substrate 21. At this point, the layer 13, the electrode 15, the layer 17, the electrode 19, and the layer 23 each continuously extends with a sensibly uniform thickness over the top face of the substrate 21. During a first photolithography and etching step, are then locally etched the layer 23, the electrode 19, and the top part of the dielectric layer 17, so that the first stair step is formed. During a second photolithography and etching step, are then locally removed, opposite to a part of a surface of the dielectric layer 17 exposed at the end of the first stair step, the bottom part of the dielectric layer 17, and the bottom electrode 15, so that the second stair step is formed.

As an example, the two etching steps are physicochemical plasma etchings implemented by means of plasmas having different formulations.

The etching of the stack in two stages allows the layers 23 and 17 and the electrodes 15 and 19 to be etched without etching the layer 13. The layers 23 and 13 both being, for example, aluminium-based layers, the top part of the stack (for example at least the layer 23) is etched using an etching being non-selective as regards aluminium, and the bottom part of the stack (for example at least the electrode 15) is etched using an etching being selective as regards aluminium. The conductive layer 23, the electrode 19, and the top part of the dielectric layer 17 are, for example, etched by a chlorinated-plasma physicochemical etching. The electrode 15 and the bottom part of the dielectric layer 17 are for example etched by a fluorinated-plasma physicochemical etching.

The chlorinated-plasma physicochemical etching however causes, during the etching of the layer 23, the creation of aluminium-based residues that deposit on the sides of the etched area. These residues are, for example, conductive ant may induce a shorting or breakdown chance of the capacitor. The first and second stair steps respectively formed between the top face of the layer 23 and the top face of the layer 17 and between the top face of the layer 17 and the top face of the layer 13 aim at reducing this issue. Indeed, these stair steps allow an horizontal distance el to be introduced between on one hand the sides of the layers 23 and 19 and the top part of the layer 17, and on the other hand, the side of the bottom part of the layer 17 and of the electrode 15, thus reducing the failure chances, such as a shorting, related to the presence of the residues generated during the first etching step.

A limit of the structure of FIG. 1 lays in that its fabrication implies two photolithography steps in order to form the first and second stair steps, respectively. As a result, the manufacturing costs are high.

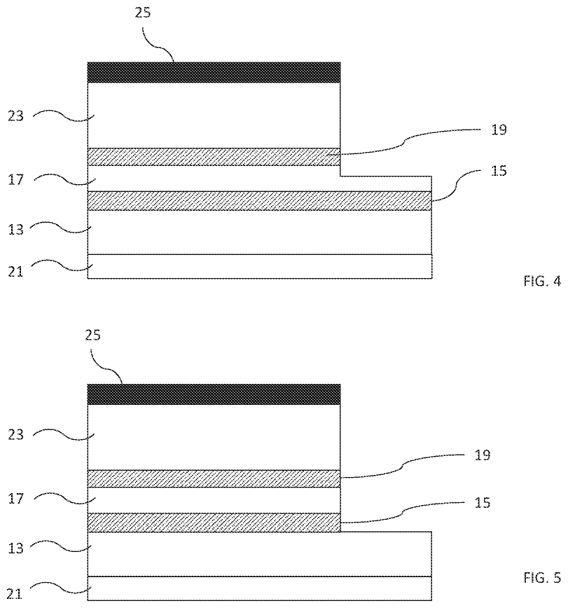

FIG. 2, FIG. 3, FIG. 4, and FIG. 5 illustrate successive steps of an example method of fabricating a capacitor according to another embodiment.

FIG. 2 illustrates a starting stack successively comprising from a top face of the substrate 21, the first conductive layer 13, the first electrode 15, the dielectric layer 17, the second electrode 19, and the second conductive layer 23.

The layers 13, 17, and 23, and the electrodes 15, and 19 are similar to the layers 13, 17, and 23 and electrodes 15, and 19 described in relation with FIG. 1. Moreover, these layers and electrodes are arranged similarly to that described in relation with FIG. 1, except that the layers 13, 17, and 23 and the electrodes 15, and 19 are, at this point, aligned. Particularly, the electrodes 15, and 19 and the layers 13, 17, and 23 each extends over the whole top surface of the substrate 21.

FIG. 3 illustrates a structure obtained at the end of a step of formation a masking layer 25 over the top face of the structure illustrated at FIG. 2. As an example, the masking layer 25 is formed by photolithography.

To this end, the masking layer 25 is for example at a first stage whole wafer formed over the top face of the layer 23, and for example contacting the latter. The masking layer 25 is, at a second stage, for example locally exposed to a light radiation, for example an ultraviolet radiation (UV), through a photolithography mask. After developing and rinsing, the layer 25 is maintained opposite to a part of the stack where the capacitor is to be formed and all about removed.

The masking layer 25 is for example made of a resin, such as a light-sensitive resin.

FIG. 4 illustrates a structure obtained at the end of a first step of etching a top part of the stack of the structure illustrated in FIG. 3.

During this step, one comes more precisely etching, by a chlorinated-plasma physicochemical etching, through the masking layer 25, a top part of the stack of the layers 23, 19, and 17. Even more precisely, during this step, are etched the conductive layer 23, the electrode 19, and a top part of the dielectric layer 17 through the masking layer 25. As an example, during this step, the conductive layer 23, the electrode 19, and a top part of the dielectric layer 17 are removed outside the opposite to the masking layer 25.

During this step, the chlorinated-plasma physicochemical etching is terminated within the dielectric layer 17.

The chlorinated-plasma physicochemical etching is, for example, a vertical anisotropic etching. It is directive, and it mainly occurs along one single preferential direction, herein the vertical direction in the orientation of FIG. 4 (that is a direction perpendicular with respect to the top face of the substrate 21).

As an example, the etching step is implemented using a plasma the pressure of which is, for example, comprised between 5 mTorr (i.e. 0.67 Pa) and 100 mTorr (i.e. 13.33 Pa), for example comprised between 10 mTorr (i.e. 1.33 Pa) and 50 mTorr (i.e. 6.67 Pa), for example in the order of 15 mTorr (i.e. 2 Pa). During this step, the source power is for example comprised between 100 W and 1800 W, for example comprised between 150 W and 800 W, for example in the order of 400 W. During this step, the biasing power is for example comprised between 20 W and 1000 W, for example comprised between 50 W and 500 W, for example comprised between 150 W and 300 W. During this step, chlorine (Cl₂) is for example injected in the plasma source. The rate of the chlorine is for example comprised between 10 sccm (or cm³·min⁻¹ at 0° C. and under atmospheric pressure) and 500 sccm, for example comprised between 50 sccm and 120 sccm, for example in the order of 80 sccm. During this step, boron trichloride (BCl₃) is for example injected in the plasma source. As an example, during this step, the rate of the boron trichloride is comprised between 10 sccm and 500 sccm, for example comprised between 20 sccm and 100 sccm, for example in the order of 50 sccm. During this step, boron trichloride and chlorine are for example injected in the plasma source. During this step, boron trichloride and chlorine are for example injected in the plasma source, for example at the above recited rates. As an example, during this step, the temperature of the bottom electrode is comprised between 20° C. and 100° C., for example comprised between 30° C. and 70° C., for example in the order of 50° C. As an example, during this step, the temperature of the top electrode is comprised between 20° C. and 100° C., for example comprised between 50° C. and 90° C., for example in the order of 70° C.

FIG. 5 illustrates a structure obtained at the end of a second step of etching a bottom part of the stack of the structure illustrated in FIG. 4.

The masking layer 25 is not removed at the end of the chlorinated-plasma physicochemical etching described in relation with FIG. 4, it is indeed kept in place during the fluorinated-plasma physicochemical etching step described in relation with FIG. 5. Both the physicochemical etching steps are thus performed through the same masking layer 25.

During this step, one more precisely comes etching, by a fluorinated-plasma physicochemical etching, through the masking layer 25, a bottom part of the stack of the layers 23, 19, 17, and 15. Even more precisely, during this step, one comes etching a bottom part of the dielectric layer 17, and the electrode 15 through the masking layer 25. As an example, during this step, the bottom part of the dielectric layer 17, and the electrode 15 are removed outside the opposite to the masking layer 25.

The fluorinated-plasma physicochemical etching has the advantage of etching the bottom part of the dielectric layer 17, and the electrode 15 in a selective manner with respect to the layer 13, including for example aluminium. During this step, the fluorinated-plasma physicochemical etching thus stops on the top face of the layer 13 without etching the latter.

The fluorinated-plasma physicochemical etching is for example a vertical anisotropic etching. It is directive and it mainly occurs along one single preferential direction, herein the vertical direction in the orientation of FIG. 5.

As an example, the etching step is performed by means of a plasma the pressure of which is for example comprised between 5 mTorr (i.e. 0.67 Pa) and 100 mTorr (i.e. 13.33 Pa), for example comprised between 5 mTorr (i.e. 0.67 Pa) and 50 mTorr, (i.e. 6.67 Pa) for example in the order of 10 mTorr (i.e. 1.33 Pa). During this step, the source power is for example comprised between 100 W and 1800 W, for example comprised between 150 W and 800 W, for example in the order of 500 W. During this step, the biasing power is for example comprised between 20 W and 1000 W, for example comprised between 20 W and 500 W, for example in the order of 50 W. During this step, sulfur hexafluoride (SF 6) is for example injected in the plasma source. The rate of sulfur hexafluoride power is for example comprised between 10 sccm (or cm³·min⁻¹ at 0° C. and under atmospheric pressure) and 500 sccm, for example comprised between 20 sccm and 80 sccm, for example in the order of 50 sccm. During this step, argon (Ar) is for example injected in the plasma source. As an example, during this step, the rate of argon is comprised between 10 sccm and 500 sccm, for example comprised between 10 sccm and 100 sccm, for example in the order of 20 sccm. During this step, sulfur hexafluoride and argon are for example injected in the plasma source. As an example, during this step, sulfur hexafluoride and argon are for example injected in the plasma source at the abovementioned rates. As an example, during this step, the temperature of the bottom electrode is comprised between 20° C. and 100° C., for example comprised between 30° C. and 70° C., for example in the order of 50° C. As an example, during this step, the temperature of the top electrode is comprised between 20° C. and 100° C., for example comprised between 50° C. and 90° C., for example in the order of 70° C.

As an example, both the fluorinated- and chlorinated-plasma physicochemical etching steps are performed in two etching settlements of the same type.

The masking layer 25 is removed at the end of the step of etching the bottom part of the dielectric layer 17 and of the electrode 15 using a fluorinated-plasma.

The masking layer 25 is, for example, removed during a stripping step. This step corresponds for example to a downstream plasma physicochemical etching. As an example, this step is performed in the same etching settlement as the chlorinated-plasma physicochemical etching step (FIG. 4) and/or the fluorinated-plasma physicochemical etching step (FIG. 5). As an example, the stripping step of the masking layer 25 is performed under a pressure, for example comprised between 300 mTorr (i.e. 40 Pa) and 1200 mTorr (i.e. 160 Pa), for example comprised between 600 mTorr (i.e. 80 Pa) and 1000 mTorr (i.e. 133.32 Pa), for example comprised between 750 mTorr (i.e. 100 Pa) and 900 mTorr (i.e. 120 Pa). During this step, the RF power is for example comprised between 600 W and 1800 W, for example comprised between 800 W and 1500 W, for example in the order of 1100 W. During this step, oxygen (O₂) is for example injected in the plasma source. The rate of oxygen is for example comprised between 500 sccm and 1200 sccm, for example comprised between 700 sccm and 1000 sccm, for example in the order of 810 sccm. During this step, water vapour (H₂O) is for example injected in the plasma source. The rate of water vapour is for example comprised between 10 sccm and 1000 sccm, for example comprised between 50 sccm and 700 sccm, for example in the order of 90 sccm or in the order of 630 sccm. As an example, during this step, water vapour and oxygen are injected in the plasma source. As an example, during this step water vapour and oxygen are injected in the plasma source at the aforementioned rates. As an example, the stripping step has a duration comprised between 1 sec and 150 sec, for example comprised between 2 seconds and 120 seconds, for example comprised between 5 seconds and 90 seconds.

The top face of the conductive layer 23, the top face of the layer 13, and the sides of the layers 23, 17, and 13, and the electrodes 19, and 15 are, for example, following the stripping step, cleaned. This step allows, for example, removing the residues for example polymeric residues from the masking layer 25 and present at the surface of the conductive layer 23. As an example, this step further allows removing the etching residues of the layers 23, and 17, and of the electrodes 19, and 15 formed on the sides of these same layers and electrodes. This step is for example performed using a solvent.

As an example, this step is performed using a solvent based on 2-(2-aminoethoxy)ethanol and on hydroxylamine. As an example, this step is performed using a solvent based on 2-(2-aminoethoxy)ethanol, on hydroxylamine, on pyrocatechol, and on hydroquinone.

As an example, this step is performed using a solvent based on 2-(2-aminoethoxy)ethanol the content of which is for example comprised between 35% and 80%, for example comprised between 55% and 65%, and on hydroxylamine the content of which is for example comprised between 10% and 20%. As an example, this step is performed using a solvent based on 2-(2-aminoethoxy)ethanol the content of which is for example comprised between 35% and 80%, for example comprised between 55% and 65%, and on hydroxylamine the content of which is for example comprised between 2% and 35%, for example comprised between 10% and 20%, on pyrocatechol the content of which is for example comprised between 1% and 20%, for example comprised between 3% and 10%, and on hydroquinone the content of which is for example comprised between 0.001% and 1%, for example comprised between 0.01% 0.1%. The above % are each % weight.

As an example, this step is performed using a solvent of the type marketed under the reference EKC265 by DuPont Inc.

At the end of the method described in relation with the FIGS. 3 to 5, the layers 17, and 23 and the electrodes 15, and 19 have their sides sensibly vertically aligned.

One should however notice that, depending on the used materials, the etching speed of the electrodes 15, and 19 may be lightly higher than that of the layers 17, and 23. In such case, at the end of the etching steps, the sides of the electrodes 15, and 19 may present a recess relative to the side of the layers 17, and 23.

At the end of the method described in relation with the FIGS. 2 to 5, a metal pad, not illustrated, made for example of copper, is for example arranged on and contacts the top face of the conductive layer 23.

An advantage of the present embodiment is related to the selection of the etching formulations, to the stripping mode, and to the selection of the cleaning which allow the formation of conductive residues on the sides of the etched area to be limited.

One can thus dispense with the formation of the stair steps (guard distance el) described in relation with FIG. 1.

An advantage is that it allows reducing the number of steps and thus the manufacturing cost of a capacitor with respect to a method of the type described in relation with FIG. 1. Particularly, the method described in relation with FIGS. 2 to 5 comprises a single photolithography step (a single photolithography mask), as compared to two in the method described in relation with FIG. 1.

Various embodiments and variants have been described. Those skilled in the art will understand that certain features of these embodiments can be combined and other variants will readily occur to those skilled in the art. In particular, while the chlorinated-plasma physicochemical etching has been described as stopping within the layer 17, the physicochemical etching could be stopped on the top face of the dielectric layer 17.

Finally, the practical implementation of the embodiments and variants described herein is within the capabilities of those skilled in the art based on the functional description provided hereinabove.

1. A method of fabricating a capacitor, comprising the following successive steps of:
a) forming a stack including, in order from the top face of a first conductive layer, a first electrode, a dielectric layer, a second electrode, and a second conductive layer;
b) forming by photolithography, a masking layer on a face of the second conductive layer opposite to the second electrode;
c) etching by a chlorinated physicochemical plasma etching, through said masking layer, a top part of the stack, said chlorinated physicochemical plasma etching being stopped within the dielectric layer;
d) etching by a fluorinated physicochemical plasma etching, through said masking layer, a bottom part of the stack, said fluorinated physicochemical plasma etching being stopped on the top face of the first conductive layer; and
e) removing the masking layer by a stripping method, then cleaning the etched sides by a cleaning method.

2. The method according to claim 1, wherein the first conductive layer is an aluminum-based layer.

3. The method according to claim 1, wherein the second conductive layer is an aluminum-based layer.

4. The method according to claim 1, wherein in step c), chlorine and boron trichloride are injected in the plasma source.

5. The method according to claim 4, wherein in step c), the chlorine is injected at a rate comprised between 50 sccm and 120 sccm, for example in the order of 80 sccm, and the boron trichloride is injected at a rate comprised between 20 sccm and 100 sccm, for example in the order of 50 sccm.

6. The method according to claim 1, wherein in step c), the plasma pressure is comprised between 1.33 Pa and 6.67 Pa, for example in the order of 2 Pa, the source power is comprised between 150 W and 800 W, for example in the order of 400 W, and the biasing power is comprised between 50 W and 500 W, for example comprised between 150 W and 300 W.

7. The method according to claim 1, wherein in step d), sulfur hexafluoride and argon are injected in the plasma source.

8. The method according to claim 7, wherein in step d), the sulfur hexafluoride is injected at a rate comprised between 20 sccm and 80 sccm, for example in the order of 50 sccm, and argon is injected at a rate comprised between 10 sccm and 100 sccm, for example in the order of 20 sccm.

9. The method according to claim 1, wherein in step c), the plasma pressure is comprised between 0.67 Pa and 6.67 Pa, for example in the order of 1.33 Pa, the source power is comprised between 150 W and 800 W, for example in the order of 500 W, and the biasing power is comprised between 20 W and 500 W, for example in the order of 50 W.

10. The method according to claim 1, wherein in step e), the cleaning method comprises the cleaning of the top face and of the sides of the second conductive layer, of the sides of the second electrode, of the dielectric layer, of the first electrode, and of the top face of the first conductive layer.

11. The method according to claim 10, wherein the step of stripping is performed by a physicochemical plasma etching.

12. The method according to claim 11, wherein in the step of stripping, dioxygen and water vapour are injected in the plasma source.

13. The method according to claim 12, wherein in the step of stripping, the dioxygen is injected at a rate comprised between 700 sccm and 1000 sccm, for example in the order of 810 sccm, and the water vapour is injected at a rate comprised between 50 sccm and 700 sccm, for example in the order of 90 sccm or in the order of 630 sccm.

14. The method according to claim 11, wherein in the step of stripping, the plasma pressure is comprised between 80 Pa and 133.32 Pa, for example comprised between 100 Pa and 120 Pa and the RF power is comprised between 800 W and 1500 W, for example in the order of 1100 W.

15. The method according to claim 10, wherein the step of cleaning is performed using a solvent based on 2-(2-aminoethoxy)ethanol and on hydroxylamine.

16. The method according to claim 15, wherein the content of 2-(2-aminoethoxy)ethanol in the solvent is comprised between 55% and 65% and the content of hydroxylamine is comprised between 10% and 20%, wherein each % is % weight.
